(19) United States
(12) Patent Application Publication
(10) Pub. No.: US 2012/0098120 A1
(43) Pub. Date: Apr. 26, 2012

(54) CENTRIPETAL LAYOUT FOR LOW STRESS CHIP PACKAGE

(75) Inventors: Chen-Hua Yu, Hsin-Chu (TW); Hao-Yi Tsai, Hsinchu City (TW); Jiun Yi Wu, Zhongli City (TW); Tin-Hao Kuo, Hsinchu City (TW)

(73) Assignee: TAIWAN SEMICONDUCTOR MANUFACTURING COMPANY, LTD., Hsin-Chu (TW)

(21) Appl. No.: 12/908,946

(22) Filed: Oct. 21, 2010

(51) Int. Cl. H01L 23/48; H01L 21/60

(52) U.S. Cl. 257/737; 438/121; 257/E23.021; 257/E21.506

(57) ABSTRACT

A low-stress chip package is disclosed. The package includes two substrates. The first substrate includes an array of first conductive structures in the corner area of the chip, and an array of second conductive structures in the peripheral edge area of the chip. The first and second conductive structures each has a conductive pillar having elongated cross section in the plane parallel to the first substrate and a solder bump over the pillar. The package also includes a second substrate having an array of metal traces. The elongated pillars each form a coaxial bump-on-trace interconnect with a metal trace respectively. The long axis of the elongated cross section of a pillar in the corner area of the chip points to chip's center area, and the long axis of the elongated cross section of a pillar in chip's peripheral edge area aligns perpendicular to the edge.

### BACKGROUND

This disclosure relates generally to integrated circuits, and more particularly to an interconnection structure in a semiconductor chip.

Integrated circuits are typically formed on a substrate such as a semiconductor wafer. Bonding bumps (bump-on-trace) are part of the interconnecting structure in an integrated circuitry. A bump provides an interface to an integrated circuit device through which an electrical connection to the device may be made. Conventional techniques may be used to provide a connection from a package terminal to an integrated circuit using the thermocompression or thermosonic wire bonding and other techniques known in the art.

Chip interconnection techniques such as the flip chip, also known as Controlled Collapse Chip Connection or its acronym, C4, interconnect semiconductor devices to external circuitry with solder bumps that have been deposited onto the chip output contacts. The solder bumps are deposited on the chip pads on the top side of the wafer during the final wafer processing step. In order to mount the chip to external circuitry (e.g., a circuit board or another chip or wafer), the chip is flipped over so that its top side faces down, and its contacting pads overlay with matching pads on the external circuitry, and then the solder is flowed between the flipped chip and the substrate supporting the external circuitry to complete the interconnect. This is in contrast to wire bonding, in which the chip is mounted upright and wires are used to interconnect the chip pads to external circuitry. The resulting completed flip chip package is much smaller than a traditional carrier based system, because the chip sits right on the circuit board. When the interconnect wires are much shorter, the inductance and resistive heat are greatly reduced. Therefore, flip chip allows higher-speed devices.

Recent trends in high-density flip chip interconnects have led to the use of round or round-like copper pillar solder bumps for CPU and GPU packaging. Copper pillar solder bumps are an attractive replacement for traditional solder bumps, because they provide a fixed stand-off independent of the bonding wire pitch. This is critical because most of the high-density circuits are under filled with a viscous polymer-like adhesive mixture, and a smaller standoff may create difficulties in getting the underfilling adhesive to flow under the die.

However, conventional round copper pillar solder bumps have several disadvantages. One is the size of a round shaped copper pillar solder bump adds to the interconnecting structure, limiting the pitch dimension of metal trace lines for the interconnect. Therefore, the current round shaped solder bumps will eventually become a bottleneck to the continuous device shrinking in IC industry.

Another disadvantage is the mechanical stress at the packaging circuitry as well as the underlying layers. This stress results from mismatched thermal expansion of the chip and the packaging structure. The stress is particularly critical in circuitry having extra low K (ELK) dielectric layers when K is lower than 3. The packaging has become more and more fragile, leading to layer separation.

In addition, the large electrical current density at the solder bump-to-pad interface contributes to electromigration and electric stress. Examples of types of damage from electromigration include microcracking in solder joints and delamination in bonding layers.

As such, a low stress interconnecting circuitry allowing high density pitch is desired.

### SUMMARY

The present disclosure describes many different embodiments of the present invention. One embodiment is A device comprising: a chip on a first substrate; a conductive structure formed on the chip, the conductive structure comprising a conductive pillar and a solder bump formed over the pillar, wherein the conductive structure has an elongated cross section in a plane parallel to the first substrate; a metal trace formed on a second substrate facing the chip; a solder resister layer formed over the second substrate, the solder resister layer having an opening over the metal trace; and the conductive structure on the chip and the metal trace in the opening of the solder resister layer formed a bump-on-trace interconnect, wherein a long axis of the elongated cross section of the conductive structure is coaxial to the trace, and the trace is aligned to point to a center portion of the chip.

Another embodiment is a device comprising: a chip on a first substrate, the chip having a central area, a corner area, and a peripheral edge area; an array of first conductive structures having elongated cross sections formed in the corner area of the chip, the first conductive structures each comprising a conductive pillar and a solder bump formed on the pillar; an array of second conductive structures having elongated cross sections formed in the peripheral edge area of the chip, the second conductive structures each comprising a conductive pillar and a solder bump formed over the pillar; an array of metal traces on a second substrate facing the first substrate; and the first and second conductive structures each forming a coaxial bump-on-trace interconnect with the metal traces respectively, wherein a long axis of the elongated cross section of the first conductive structure in the corner area of the chip points to the center area of the chip, and a long axis of the elongated cross section of the second conductive structure in the peripheral edge area of the chip aligns perpendicular to the chip's edge.

The present disclosure also provides a method for fabricating a chip packaging array. In one embodiment, a method of manufacturing a low stress chip package array, comprising: a) providing a chip on a first substrate; b) dividing the chip into a central area, a corner area, and a peripheral edge area; c) generating a plurality of first conductive pillars in the corner area of the chip, the pillars having elongated cross sections in a plane parallel to the first substrate; d) generating a plurality of second conductive pillars in the peripheral edge area of the chip, the pillars having elongated cross sections in a plane parallel to the first substrate; e) forming a solder bump over each of the first and second conductive elongated pillars; f) forming a plurality of trace lines on a second substrate; g) coating a layer of solder resister over the second substrate; h) forming a plurality of openings over the trace lines in the solder resister layer; i) flipping the second substrate to face the first substrate; and j) connecting the first and second conductive elongated pillars to the trace lines via the solder bump, wherein the long axes of the elongated cross sections of the first and second conductive pillars are coaxial with the corresponding trace lines, and wherein the first conductive elongated pillars in the corner area of the chip align along a diagonal line of the chip and the second conductive elongated pillars in the peripheral edge area of the chip align perpendicular to the chip's edge.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1A-1B show a top view and a cross sectional view of a conventional round shaped Cu pillar bump-on-trace interconnect;

FIG. 2 shows the top view of an embodiment of the elongated bump-on-trace structure and a top view of a conventional round bump-on-trace structure;

FIG. 3 shows the corresponding sectional views of an embodiment of the elongated bump-on-trace structure and a conventional round bump-on-trace structure as in FIG. 2, the cross section is viewed from a plane perpendicular to the trace;

FIG. 4 shows the top views of three exemplary elongated bump-on-trace structures according to various aspects of the present disclosure;

FIG. 5 shows a top view of an array of the elongated bump-on-trace structures according to an embodiment in FIG. 2, and a top view of an array of the conventional round bump-on-trace structures as in FIG. 1.

FIGS. 6A-6B illustrate the sectional view of the elongated bump-on-trace structure according to an embodiment disclosed in FIG. 3, and the sectional view of a conventional round bump-on-trace structure, the cross section is viewed from a plane along the trace;

FIG. 7A illustrates shapes of some elongated bump-on-trace structures consistent with alternative embodiments of the current disclosure, and FIG. 7B illustrates shapes of round or round-like bump-on-trace structures;

FIG. 8 illustrates a number of traces for connecting to the elongated bump-on-trace structures;

FIG. 9 illustrates relative position and size of an elongated bump to a trace line;

FIG. 10 illustrates relative locations of elongated bumps to trace lines;

FIG. 11 illustrates a centripetal layout diagram 1100 of a bump-on-trace interconnect consistent with an embodiment;

FIG. 12 shows a summary diagram of elongated interconnects in corners and peripheral areas of a chip;

FIG. 13 illustrates a centripetal interconnect layout at a chip's corner, according to some embodiments of the current disclosure;

FIG. 14A shows typical directions of mechanical stress on a flip chip package; and

FIG. 14B shows a stress vector on a centripetal elongated interconnect;

FIG. 14C shows a centripetal interconnect layout in different areas of a chip, consistent with another embodiment of the present disclosure;

FIG. 15 shows a number of options for opening the solder resist;

FIG. 16 illustrates a flowchart of a method for fabricating a centripetal layout structure according to various aspects of the present disclosure.

### DETAILED DESCRIPTION

It is understood that the following disclosure provides many different embodiments, or examples, for implementing different features of the embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact. Additionally, descriptive terms such as upper/lower, top/bottom, and vertical/horizontal are used for ease of description and do not provide any limitation to an absolute direction. For example, an upper layer and a lower layer may indicate a respective relationship relative to a substrate or integrated circuit formed on a substrate, rather than absolute direction.

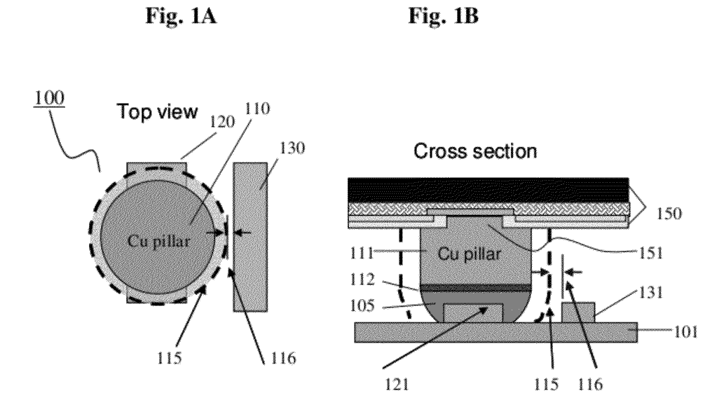

Referring now to FIG. 1A and FIG. 1B, shown are the top view and cross sectional view of a conventional round shaped Cu pillar bump-on-trace structure 100 which may be formed on an integrated circuit interconnecting a metal line trace on a substrate. In top view, a round shaped Cu pillar bump 110 is formed over a metal trace 120 and next to a neighboring trace 130. An extra ring area 115 is drawn to include the possible bump size change from design modifications, which results in reduction of space 116 between the Cu bump and the neighboring trace 130. FIG. 1B shows the corresponding structure's cross section along a plane perpendicular to the trace. An integrated circuitry typically includes conductive, insulative, and semiconductor layers patterned to form the circuit. The circuit may include an interconnect structure or portion of it 150 containing an opening 151 (e.g., multilayer interconnect (MLI) or a plurality of conductive traces and interlayer dielectric with an opening for electrical contact) to which the Cu layer is deposited first, followed by a solder interfacial layer. A patterning process, for example, lithography and etch, is applied on the Cu and solder interfacial layer to define the interconnecting Cu pillar structure 111. A Cu pillars 111 connects electrically to the opening 151 of interconnect circuit 150 on one end, and is attached to a solder bump 105 through the interfacial layer 112 on the other end. The chip containing the circuit 150 is then flipped to face an interconnecting board which includes a substrate 101 and traces 121 and 131. The upper circuit 150 with pillar 111 is then positioned to overlay with traces 121 on the interconnecting substrate, to allow the solder bump 105 contacting trace 121 to form a bump-on-trace connection. In some methods, a curable adhesive is dispensed into gaps between bumps and allowed to be cured during the mating process to confine the molten solder during a reflow process. The gap 116 between the bump 111 and the neighboring trace 131 provides short-circuit protection. Therefore, an adequate gap provides a full curing process. However, the bumps are placed at a fine pitch, which can equal the smallest trace pitch of the interconnecting substrate. So this process poses a challenge for the packaging process, because the bumping and bonding pitch may be too small. Plus, the safe gap space can be easily affected by the additional bump size variation 115.

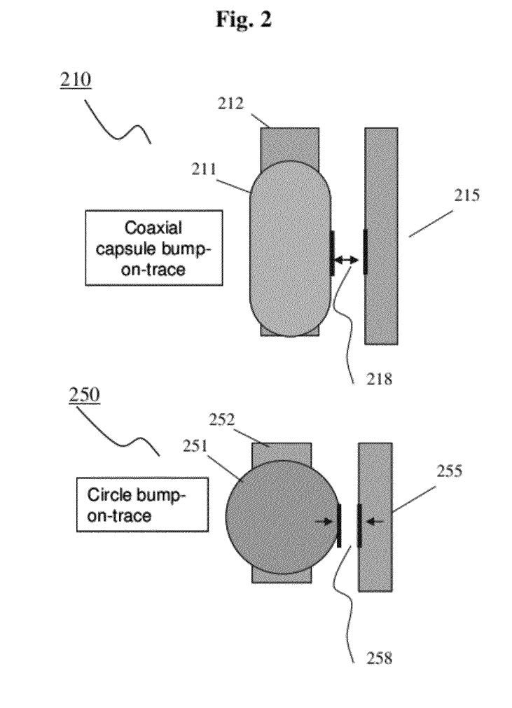

FIG. 2 illustrates a top view of an embodiment of a coaxial elongated bump-on-trace structure (e.g., an elongated bump and a metal trace connection) 210 and a top view of a conventional circular Cu bump-on-trace 250 as a reference. In the upper device, the coaxial elongated bump-on-trace structure is an elongated structure 211 on top of a trace line 212, next to a neighboring trace 215 which is separated from trace 212 by a space 218. The lower device shows a conventional circle shaped Cu pillar 251 on trace 252 forming a space 258 with the neighboring trace 255. In comparison, the coaxial elongated bump-on-trace is protected by a larger space 218 than the gap 258 formed by the circular bump-on-trace at the same bumping and bonding pitch.

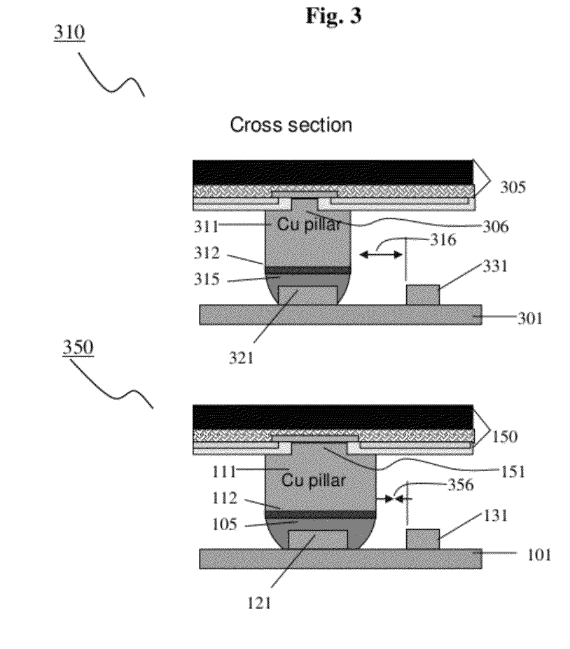

FIG. 3 illustrates a sectional view of the corresponding coaxial elongated bump-on-trace structure 310 as the embodiment in FIG. 2 and the sectional view of a similar conventional circular Cu pillar structure 350 as a reference, similar to the structure 100 in FIG. 1B. The cross section is perpendicular to the trace's length. The coaxial elongated Cu pillar bump-on-trace structure may be formed on an integrated circuit interconnecting a metal line trace on a substrate. The integrated circuitry typically includes patterned conductive, insulative, and semiconductor layers. The circuit may include an interconnect structure or portion of it 305 containing an opening 306 to which the Cu layer is deposited first, followed by a solder interfacial layer. A patterning process, for example, lithography and etch, is applied on the Cu and solder interfacial layer to define the interconnecting elongated Cu pillar structure. The elongated Cu pillar 311 connects electrically to the opening 306 of interconnect circuit 305 on one end, and is attached to a solder ball 315 through the interfacial layer 312 on the other end. The solder ball 315 stretches to an elongated shape at the end surface of the elongated pillar. The chip containing the circuit 305 is then flipped to face an interconnecting board which includes a substrate 301, traces 321 and 331. The upper circuit 305 with structure formed of 311, 312 and 315 is then positioned to overlay with trace 121 on the interconnecting substrate, to allow the elongated solder bump 315 and trace 321 to form an elongated bump-on-trace connection. The elongated Cu pillar structure 311 is separated from a neighboring trace 331 by a space 316.

The lower sectional view shows a conventional structure 350 having a circular shaped Cu pillar 111. 111 connects at one end to an opening 151 in an integrated circuitry or a portion of it 150, and at the other end connects to its solder interfacial layer 112 and solder bump 105. The conventional pillar stack positioned on trace 121 forms a space 356 from the neighboring trace 131. As a comparison, the coaxial elongated bump-on-trace structure has a larger space 316 than the gap 356 formed by the circular bump-on-trace at the same bumping and bonding pitch.

The elongated bump-on-trace structure may include a copper pillar; however, the pillar material should not be limited to copper only. Examples of other materials suitable for the pillar include aluminum, aluminum/silicon/copper alloy, titanium, titanium nitride, tungsten, polysilicon, metal silicide (such as nickel silicide, cobalt silicide, tungsten silicide, tantalum silicide, titanium silicide, platinum silicide, erbium silicide, palladium silicide, or combinations thereof), copper, copper alloy, titanium, titanium nitride, tantalum, tantalum nitride, tungsten, polysilicon, and combinations thereof. The solder bumps may contain lead, or may be lead-free. The examples of solder materials include tin, copper, silver, bismuth, indium, zinc, antimony, Sn—Ag—Cu, Ag—Cu—Zn and Sn—Ag—Cu—Mn, and alloys with traces of other metals.

Examples of materials suitable for the trace lines includes metals, metal alloys, metal silicides, aluminum or aluminum alloy, copper, copper/nickel alloy, copper-IT (immersion Sn), and copper-ENEPIG (electroless nickel electroless palladium immersion gold), copper-OSP (organic solderability preservatives), and/or combinations thereof.

Examples of materials suitable for the interconnecting substrate includes non-conducting supportive layers, such as silicon oxide, a material having a low dielectric constant such as a dielectric constant (k) less than about 2.5 (e.g., extra low k (ELK)), silicon nitride, silicon oxynitride, polyimide, spin-on glass (SOG), fluoride-doped silicate glass (FSG), undoped silica glass (USG), carbon doped silicon oxide (SiOC), Black Diamond® (Applied Materials of Santa Clara, Calif.), Xerogel, Aerogel, amorphous fluorinated carbon, Parylene, BCB (bis-benzocyclobutenes), SiLK (Dow Chemical, Midland, Mich.), polyimide, and/or other suitable materials.

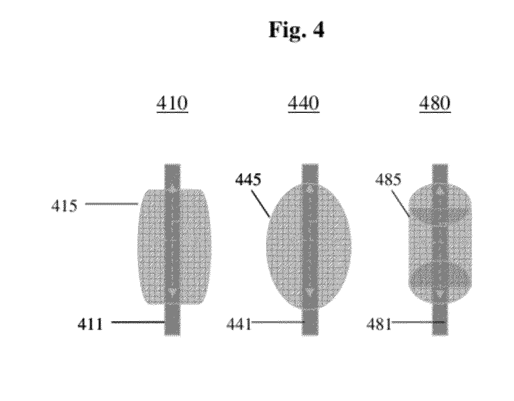

Referring now to FIG. 4, illustrated are top views of three exemplary structures consistent with embodiments of the elongated bump-on-trace structures. Structure 410 includes a bump 415 formed on trace 41, the bump shaped as a rectangular with two convex curved sides. The elongated axis of the rectangular runs coaxial, i.e., parallel or nearly parallel to the axis of trace 411. Structure 440 includes an ellipse-shaped bump 445 formed over trace 441. The long axis of the ellipse is also coaxial to trace 441. Similarly, structure 480 includes an elongated shaped bump 485 formed over trace 481. The long axis of the bump 485 is also coaxial to trace 481. The long axes of the elongated bumps align to the trace line direction to maximize the bump's side space to the closest neighboring trace. The above described characteristic of this embodiment allows more densely patterned bumping and bonding pitch and therefore tighter metal spacing design rules.

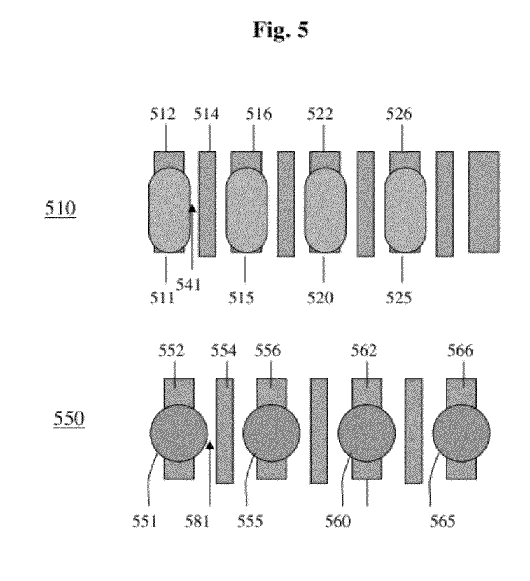

Referring to FIG. 5 now, illustrated are top views of an array of the elongated bump-on-trace structures according to an embodiment in FIG. 2 and an array of the conventional round bump-on-trace structures in FIG. 1. In the top array 510, a row of elongated bumps 511, 515, 520, and 525 are formed each respectively over alternating traces 512, 516, 522, and 526. To increase packing density, bump-on-trace joints are staggered in rows, thus bumps are only shown over every other trace in a row in FIG. 5. So a typical spacing between a bump 511 to a trace 514 is 541.

In the bottom array 550 of FIG. 5, round bumps 551, 555, 560, and 565 are formed each respectively over alternating traces 552, 556, 562, and 566, having a typical bump-to-neighboring-trace space 581 between bump 551 and trace 554. As shown in FIG. 5, more trace lines can be packed into the same area in the top array 510 than the bottom array 550 under the same bumping and bonding process design rule. Therefore, the array 510 according to the embodiment allows a tighter pitch and a broader bonding process window than the conventional array 550.

In the above embodiment, the array of coaxial elongated bump-on-trace structure (511, 515, 520, and 525) may include copper pillars; however, the pillar material should not be limited to copper only. Examples of other materials suitable for the pillars include aluminum, aluminum/silicon/copper alloy, titanium, titanium nitride, tungsten, polysilicon, metal silicide (such as nickel silicide, cobalt silicide, tungsten silicide, tantalum silicide, titanium silicide, platinum silicide, erbium silicide, palladium silicide, or combinations thereof), copper, copper alloy, titanium, titanium nitride, tantalum, tantalum nitride, tungsten, polysilicon, and combinations thereof. The solder bumps may contain lead, or may be lead-free. The examples of solder materials include tin, copper, silver, bismuth, indium, zinc, antimony, Sn—Ag—Cu, Ag—Cu—Zn and Sn—Ag—Cu—Mn, and alloys with traces of other metals.

Examples of materials suitable for the trace lines includes metals, metal alloys, metal silicides, aluminum or aluminum alloy, copper, copper/nickel alloy, copper-IT (immersion Sn), and copper-ENEPIG (electroless nickel electroless palladium immersion gold), copper-OSP (organic solderability preservatives), and/or combinations thereof.

Another advantage of the elongated coaxial bump-on-trace structure is its larger landing area on the trace than a conventional round or round like bump without increasing the bump width. Larger landing area provides larger contact surface with the trace, thus lower electrical current density through the interface. According to the Black's equation, the Mean-Time-To-Failure (MTTF) of a semiconductor circuit due to electromigration, a phenomenon of molecular rearrangement (movement) in the solid phase caused by an electromagnetic field, is proportional to the area of contact.

$$MTTF = {Awj}^{- n} {e}^{( \frac{Q}{kT} )} \qquad ( {Black}^{′} s equation )$$

A is a constant;

j is the current density;

n is a model parameter, approximately equals 2;

Q is the activation energy in eV (electron volts)

k is Boltzmann constant

T is the absolute temperature in K

w is the width of the metal wire

The Black's equation is an empirical model, which describes the failure rate dependence on the temperature, the current density induced electrical stress, and the specific techniques and materials involved. The values for A, n, and Q are found by fitting the model to experimental data. The typical current density at which electromigration occurs in Cu or Al interconnects is 106 to 107 A/cm2. However, electromigration occurs at much lower current densities. For typical solder joints, such as SnPb or lead-free SnAgCu used in IC chips today, electromigration may occur at a current density as low as 104 A/cm2. Electromigration causes a net atom transport along the direction of electron flow. The atoms accumulate at the anode, and voids are created at the cathode, so electric stress is induced at the solder interface. Due to the current crowding effect from high current densities, the voids extend to microcracks and cause a failed circuit.

Electromigration damage becomes more severe when the IC industry moved from bump-on-pad to direct bump-on-trace recently to increase interconnect density, because the bump-on-trace reduces the bonding area on the trace by half comparing to the bump-on-pad structure. To make up the lost contacting area, a conventional round shaped bump-on-trace would have to double the bump diameter. However, the overhang bump takes away the safe space from the closest neighboring trace and reduces process window for the interconnect circuitry.

An elongated bump-on-trace according to some of the embodiments provides an overall larger trace contacting interface than a conventional round shaped bump-on-trace. Increasing the length of the elongated bump-on-trace enlarges the overlapping area with the trace proportionally; meanwhile the bump's width is kept almost unchanged. Therefore, an elongated bump-on-trace has a significant advantage in reducing the electromigration damage.

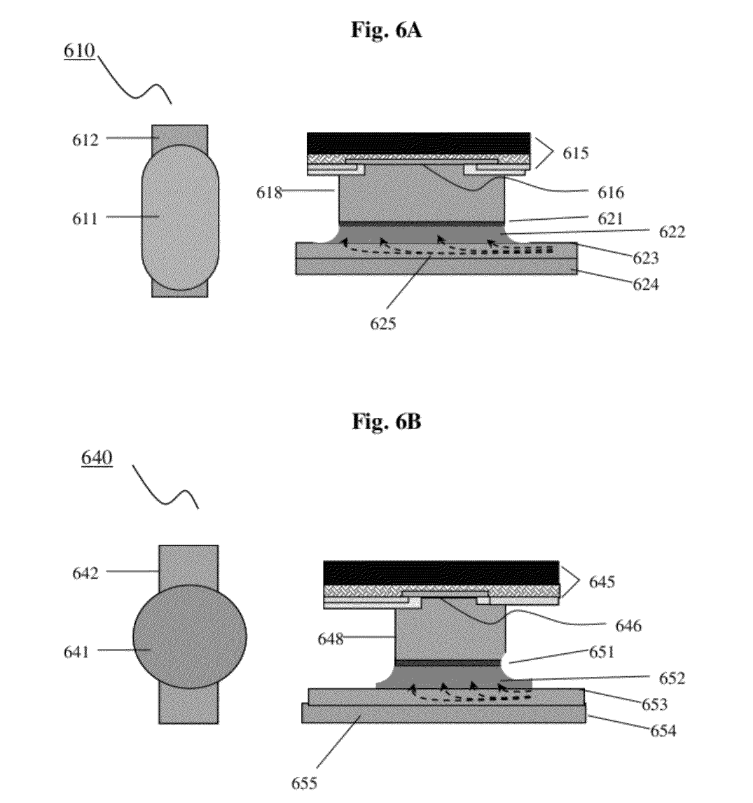

FIGS. 6A and 6B compare the top views and sectional views, cutting along the trace direction, of an elongated bump-on-trace structure in FIG. 2 and a conventional round bump-on-trace structure in FIG. 1. In FIG. 6A, the coaxial elongated structure 610 is illustrated in a top view on the left and a sectional view on the right. In the top view, an elongated bump 611 is overlaying on trace 612. In the corresponding sectional view, the elongated Cu pillar bump-on-trace structure may be formed on an integrated circuit interconnecting a metal line trace on a substrate. The circuitry may include an interconnect structure or portion of it 615 with an opening 616 to which the top end of the Cu pillar 618 is electrically connected. A solder interfacial layer 621 and a sloped solder bump 622 are formed on the bottom end of the Cu pillar 621. The side slopes shown at two sides of bump 622 are formed from the solder ball mating the trace surface. An interconnecting board including a substrate 624 and a conductive trace 623 is positioned to overlay the “flipped” chip circuit 615, to allow the solder bump 622 and trace 623 to form a bump-on-trace connection. Electric current through the interconnecting surface is represented by dashed arrow lines 625. In FIG. 6B, a top view of a conventional bump-on-trace structure 640 shows a round bump 641 overlaying on trace 642. The corresponding sectional view of structure 640 includes a circular shaped Cu pillar 648 which connects at one end to an opening 646 in an integrated circuitry or a portion of it 645, and at the other end connects to its solder interfacial layer 651 and solder bump 652. An interconnecting board including a substrate 654 and a metal trace 653 is positioned to overlay the “flipped” chip circuit 645, to allow the solder bump 652 and trace 653 to form a bump-on-trace connection. Current through the interconnecting surface is represented by dashed arrow lines 655. As shown here, electric current density for the round bump is higher than that for the elongated bumps.

The coaxial elongated bump-on-trace structure may include a copper pillar; however, the pillar material should not be limited to copper only. Examples of other materials suitable for the pillar include aluminum, aluminum/silicon/copper alloy, titanium, titanium nitride, tungsten, polysilicon, metal silicide (such as nickel silicide, cobalt silicide, tungsten silicide, tantalum silicide, titanium silicide, platinum silicide, erbium silicide, palladium silicide, or combinations thereof), copper, copper alloy, titanium, titanium nitride, tantalum, tantalum nitride, tungsten, polysilicon, and combinations thereof. The solder bumps may contain lead, or may be lead-free. The examples of solder materials include tin, copper, silver, bismuth, indium, zinc, antimony, Sn—Ag—Cu, Ag—Cu—Zn and Sn—Ag—Cu—Mn, and alloys with traces of other metals.

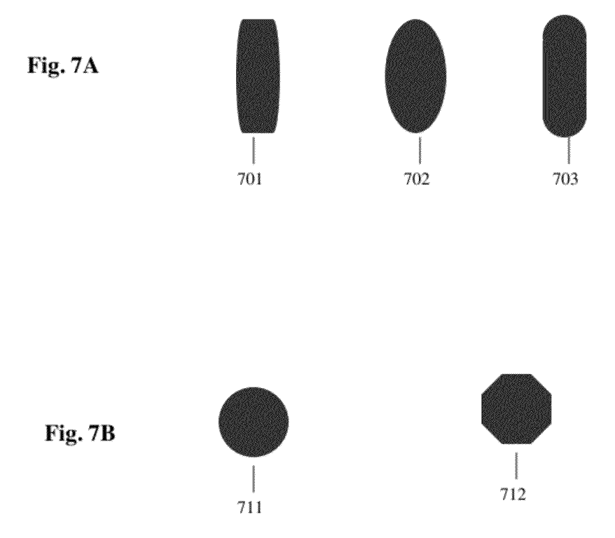

FIG. 7A illustrates a number of bump shapes consistent with alternative embodiments of the current disclosure; such shapes include a rectangular with curved sides 701, an oval 702, and a capsule 703. As comparisons, FIG. 7B shows a conventional circular bump 711 and an 8-polygon shaped bump 712.

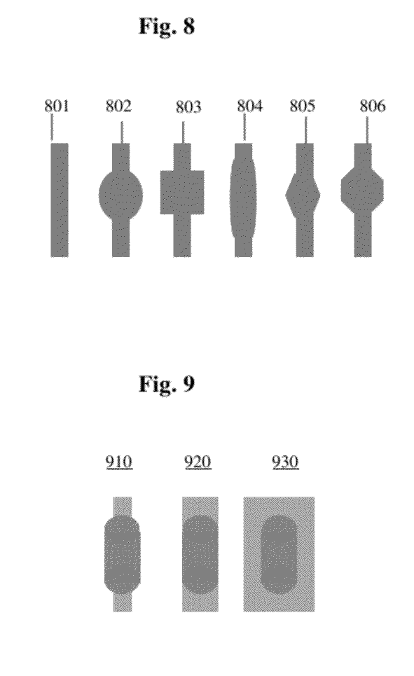

FIG. 8 shows a number of traces for connecting to the elongated bump-on-trace structures. The traces may have straight sides as in 801, may have curved sides that protrude out like a circle 802, a square 803, an oval 804, a diamond 805, or a polygon 806.

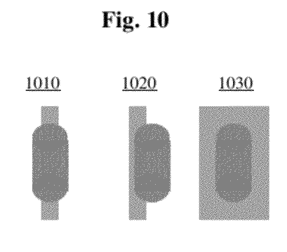

FIG. 9 illustrates relative position and size of an elongated bump to a trace line, according to some embodiments. The shorter side of the elongated bump may be wider (in 910), equal to (in 920), or narrower (in 930) than the width of trace.

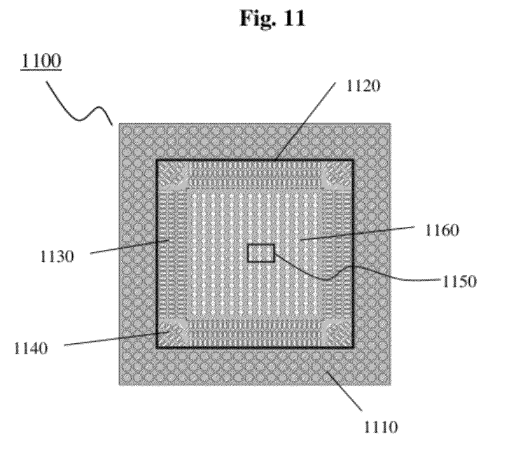

FIG. 10 illustrates relative locations of the elongated bumps to trace lines. The elongated bump may be located overhanging from the trace's center (in 1010), overlapping only a portion of the trace at one side (in 1020), or in the middle of the trace (in 1030).

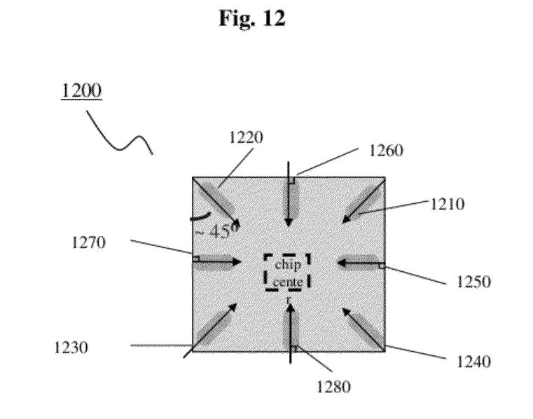

Referring to FIG. 11 now, illustrated is a centripetal layout diagram 1100 of a bump-on-trace interconnect consistent with an embodiment. The layout includes a ball grid array (BGA) mounting board 1110, a chip 1120 mounted on board 1110 with its interconnecting circuitry facing down. The interconnect diagram shown on chip 1120 is the layout image on the down-facing surface, not a top surface view. The diagram shows different characteristics of the interconnecting structures at different locations of the chip. In a central location, interconnects are characterized as round shaped pillars 1160, and at chip's peripheral, interconnects are patterned into coaxial elongated shaped pillars on traces. However, there are two types of pillar orientation for the peripheral interconnects. Along the four straight edges, interconnects 1130 are oriented perpendicular to the chip edges, and near chip's four corners, interconnects 1140 are oriented diagonally toward the chip center 1150.

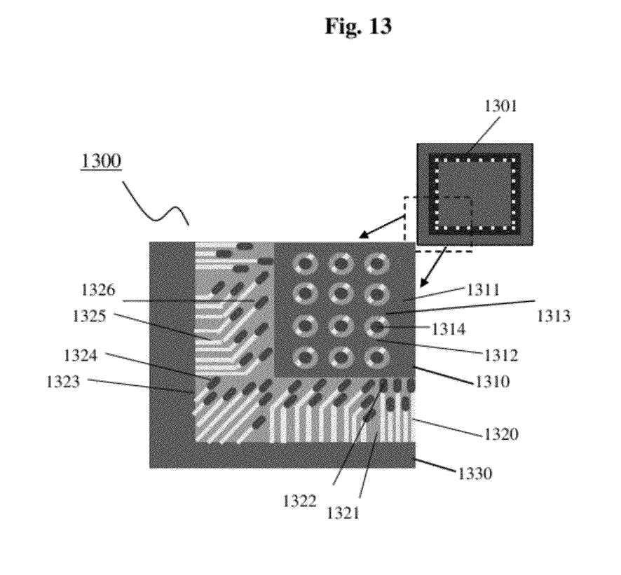

FIG. 12 shows a summary diagram 1200 of elongated interconnects in corners and peripheral areas of a chip 1200, according to the disclosed embodiment. Elongated interconnects 1210, 1220, 1230, and 1240 at the corners of chip 1200 point to chip center, forming about 45 degree angles with the adjacent edges lines. Elongated interconnects 1250, 1260, 1270, and 1280 along chip's edges are set perpendicular to the edges respectively.

Chip periphery including corners typically require minimum pitch, because they often carry higher density interconnects than the power and grounding terminals located at central area 1160. As explained above, a coaxial elongated pillar array provides tighter pitch and a broader bonding process window than a conventional round pillar array. Therefore, the coaxial elongated bump-on-trace is the interconnect of choice for the outer edges of a chip package.

In the embodiment, the array of coaxial elongated bump-on-trace structure (1230, 1240) may include copper pillars, however, the pillar material should not be limited to copper only. Examples of other materials suitable for the pillars include aluminum, aluminum/silicon/copper alloy, titanium, titanium nitride, tungsten, polysilicon, metal silicide (such as nickel silicide, cobalt silicide, tungsten silicide, tantalum silicide, titanium silicide, platinum silicide, erbium silicide, palladium silicide, or combinations thereof), copper, copper alloy, titanium, titanium nitride, tantalum, tantalum nitride, tungsten, polysilicon, and combinations thereof. The solder bumps may contain lead, or may be lead-free. The examples of solder materials include tin, copper, silver, bismuth, indium, zinc, antimony, Sn—Ag—Cu, Ag—Cu—Zn and Sn—Ag—Cu—Mn, and alloys with traces of other metals.

Examples of materials suitable for the trace lines includes metals, metal alloys, metal silicides, aluminum or aluminum alloy, copper and copper alloy, and/or combinations thereof.

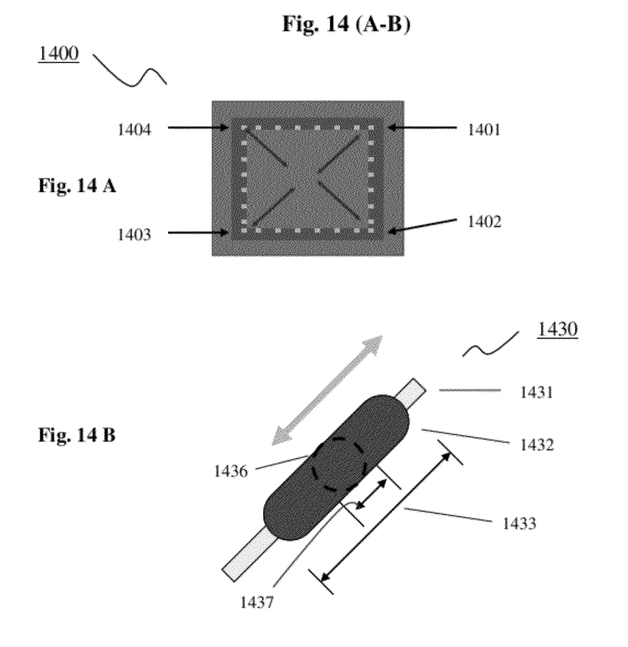

FIG. 13 illustrates a corner of the centripetal layout of an interconnect structure according to some embodiments of the current disclosure. One quarter of a chip 1301 is expanded and displayed as diagram 1300. There are three regions in this diagram 1300: the central region 1310 protected with solder resister 1311, the peripheral interconnect region 1320 without solder resister, and the chip edge 1330 covered with solder resister. In the central region 1310, solder resister is opened to circular holes 1312 for mating round pillars 1314 to exposed trace lines 1313. In the peripheral area 1320 of the chip, trace lines 1321, 1323, and 1325 in peripheral region 1320 are open lines without solder resister. Elongated shaped pillars 1322, 1324, and 1326 are patterned over interconnecting circuitry, mating coaxially to trace lines 1321, 1323, and 1325 respectively. After interconnection, 1321 and 1322 along a peripheral straight edge align perpendicular to the edge, 1323 and 1324 at a corner align diagonally pointing to the chip center, and 1325 and 1326 near a corner also point to the chip center with the help of escape trace lines.

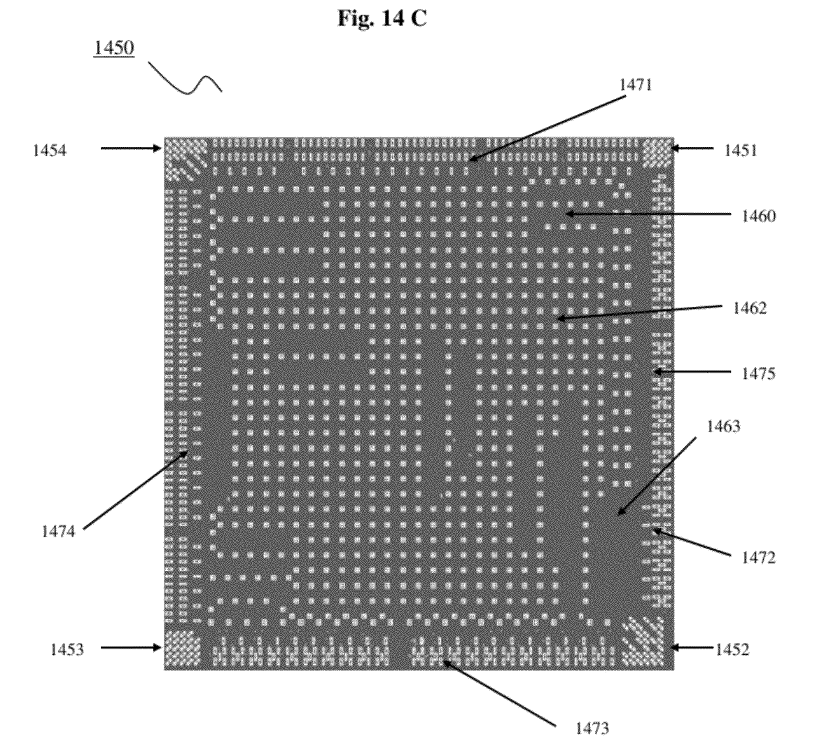

FIG. 14A shows shear stress distribution vectors on a flip chip package. Stress vectors 1401, 1402, 1403, and 1404 pull on the four corners of chip 1401 along the diagonal directions. Shear stress is most severe at four corners of the chip because the substrate's mismatched thermal shrinking and expansion. The centripetal coaxial elongated interconnect reduces the shear stress on the interface of an interconnect for at least two reasons. First, a metal trace line aligned parallel to the shear stress direction provides better support for the interfacial layer. Second, each elongated bump-to-trace contact interface has a larger interfacial area therefore lower layer stress, because an average interfacial layer shear stress is inversely proportional to the interfacial area as shown in the formula below:

$$τ = \frac{F}{A}$$

Where

τ=the shear stress

F=the force applied

A=the cross sectional area

FIG. 14B shows an exemplary shear stress vector on a centripetal elongated interconnect. In diagram 1430, an elongated pillar 1432 coaxially aligned to trace 1431 has a larger contact area (proportional to length 1433) than a conventional round pillar 1436 would have at the same trace line width 1437, therefore risks of delamination at the interfacial layers is greatly reduced.

FIG. 14C shows a centripetal interconnect layout in different areas of a chip, consistent with another embodiment of the present disclosure. Chip 1450 contains a variety of interconnect patterns having different contact densities, in both the central area and the peripheral area. For example, the power and grounding terminals located in central area 1460 and 1463 have lower pitch than those located in area 1462 inside the chip. Because high pitch can increase packaging stress and the pulling force on the chip, as discussed above and shown in FIG. 14A. It has been explained above, a coaxial elongated bump-on-trace interconnecting array enables tighter pitch and broader bonding process window than a conventional round pillar array. Therefore, arrays of coaxial elongated bump-on-trace interconnects are designed accordingly to reduce the surface stress. For example, elongated interconnects at the diagonal corners 1451 and 1453 have similar patterns, because these corners are adjacent to similarly placed power and grounding terminals. When nearby patterns on the chip differ, elongated interconnects at corners 1452 and 1454 form different layouts to accommodate their specific stress loads at corresponding corners. In the peripheral edge area, arrays maybe divided into sub-arrays having different characteristics. Peripheral layouts may include multiple rows of the elongated bump-on-trace interconnect arrays. For example, arrays 1471 and 1474 include structures having different size and different pitch; and arrays 1472, 1473, and 1475 vary in array width, length, pitch, and pattern.

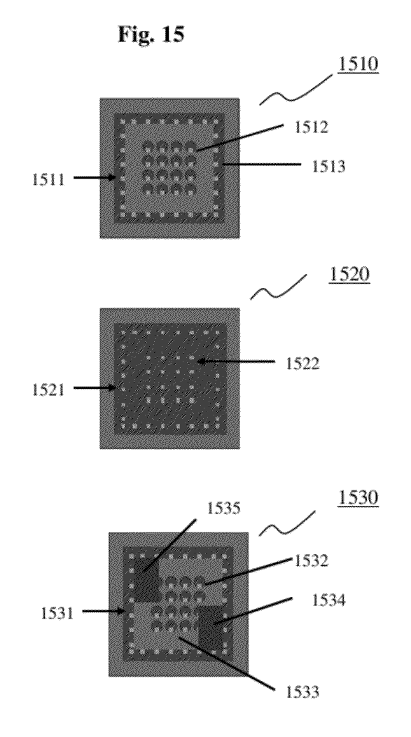

FIG. 15 shows a number of options regarding solder resister opening during the trace line patterning process on the interconnecting substrate. Where the resister is opened on the trace line, a mating solder on top of a pillar from the integrated circuit side can form an electrical contact with the trace line. But a trace resist can still be open where there is no matching solder if necessary. The adhesive under fill process after the soldering process will fill and seal the gap left by the solder resister openings around the pillars.

The first diagram 1510 represents a top view of the first option of solder opening on the trace lines, where solder resist is opened up substantially in peripheral area 1511 where minimum bumping and bonding pitch is required. Solder resister is also opened on trace surface where no Cu pillar will be landing in the peripheral for process convenience. However, in central area 1513, where power and grounding terminals do not require minimum bumping and bonding pitch, solder resister is only opened for Cu pillar landing holes 1512.

The middle diagram 1520 represents a top view of the second option of solder opening on the trace lines, where solder resister is opened up substantially in both peripheral area 1521 and central area 1522, regardless of whether the bumping and bonding pitch is minimum or not, or if the Cu pillar lands in the solder resister area 1522.

The bottom diagram represents the third option, where solder resister is opened up substantially in peripheral area 1531 where the bumping and bonding pitch is minimum. However in central area 1533, where power and grounding terminals do not require minimum bumping pitch, solder resister is opened selectively only in one or more masked areas 1534 and 1535, regardless the Cu pillars land or not in those areas.

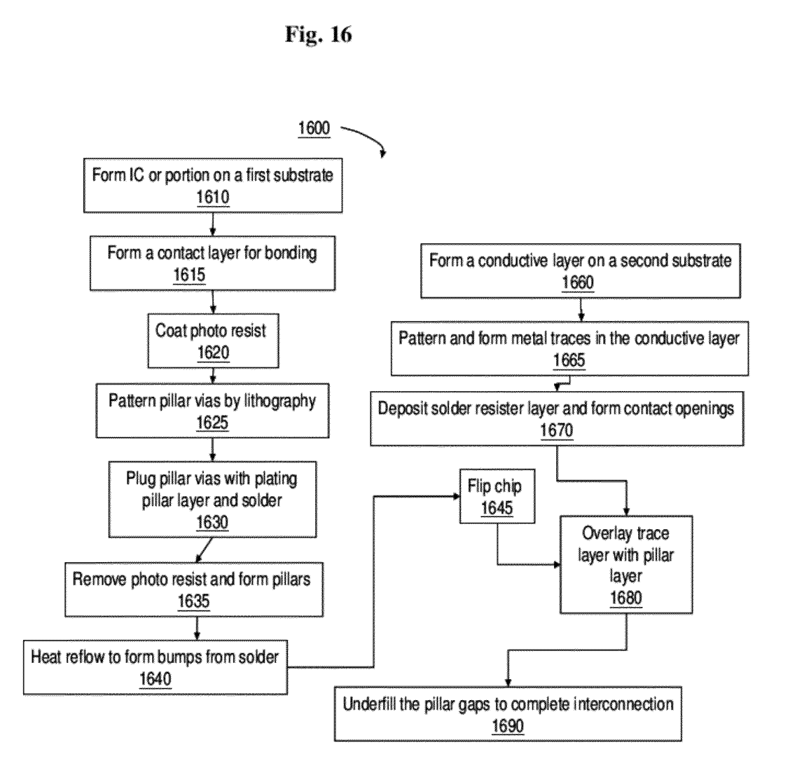

Referring now to FIG. 16, illustrated is a flowchart of a method 1600 used to form an elongated bump-on-trace structure according to one embodiment of the current disclosure. The method 1600 may be used to fabricate the set forth structures in the above figures such as structures 210, 310, 410, 440, 480, 510, 610, 910, 920, 930, 1010, 1020, 1030, 1130, 1140, 1210-1280, 1322, 1324, 1326, and 1432 described herein. It is understood that additional steps may be provided before, during, and after the method 1600, and some of the steps described below can be replaced or eliminated, for additional embodiments of the method.

The method 1600 begins at step 1610 where an integrated circuit or portion thereof is formed, or partially formed, on a first substrate. The substrate may be a semiconductor wafer such as silicon wafer. Alternatively, the substrate may include other elementary semiconductor materials such as silicon on insulator (SOI), germanium, a compound semiconductor such as silicon carbide, gallium arsenic, indium arsenide, and indium phosphide, and an alloy semiconductor material such as silicon germanium, silicon germanium carbide, gallium arsenic phosphide, and gallium indium phosphide, and/or other substrate compositions known in the art.

The integrated circuit is formed using, for example, conductive layers, semiconductor layers, and insulative layers disposed on the substrate. A contact structure at the surface of the integrated circuit for making a bonding layer is formed in step 1615. A photo resist layer is deposited on the integrated circuit surface in step 1620, patterned to the desired elongated shaped via holes in step 1625. The via holes will be plugged with pillar materials for making electrical contacts from devices of integrated circuit to package terminals. A number of plating layers are deposited in step 1630. One plating layer forms the pillar plugs in the pillar vias. Other plating layers maybe a top solder layer and an interfacial layer between the solder and the pillar layers. Photo resist is then removed in step 1635 and the desired elongated pillars are formed. The conductive pillars of the interconnect structure may include materials such as aluminum, aluminum/silicon/copper alloy, titanium, titanium nitride, tungsten, polysilicon, metal silicide, copper, copper alloy, titanium, titanium nitride, tantalum, tantalum nitride, tungsten, polysilicon, metal silicide (such as, nickel silicide, cobalt silicide, tungsten silicide, tantalum silicide, titanium silicide, platinum silicide, erbium silicide, palladium silicide, or combinations thereof), and/or other suitable materials. The interconnect pillar structure may be formed by processes including physical vapor deposition (or sputtering), chemical vapor deposition (CVD), plating, and/or other suitable processes. Other manufacturing techniques used to form the interconnect pillar structure may include photolithography processing and etching to pattern the conductive layers for vertical pillars, and may be followed by an etch back or chemical mechanical polish (CMP) process.

In a next step 1640, heat reflow is applied to the solder layer and contacting solder bumps are formed on top of the pillars. In a following step 1645, the chip containing the integrated circuit is flipped so that the solder bumps face the trace lines.

In a parallel sequence, method 1600 includes step 1660 where a conductive layer is formed on a separate second substrate, followed by step 1665 when the conductive layer is patterned to form conductive traces. The conductive layer may be performed using techniques such as photolithography processes including forming photoresist layers, bake processes, exposure processes, development processes; wet or dry etch processes; and/or other suitable processing. The method 1600 proceeds to step 1670 when a solder resister layer is deposited and patterned to form interconnect openings. A solder resister layer protects any unwanted interconnect shortage outside the defined openings where trace lines are exposed to mate with the solder pillars.

The method 1600 then proceeds to 1680 where the flipped chip from step 1645 is aligned to the second substrate and the pillars with solder tops will overlay the conductive traces to form interconnect. A number of processes, for example, heat air reflow or a thermosonic bonding may be applied to liquidize solder tips to form interconnection. Step 1290 completes the bonding by underfilling the gaps around the pillars with adhesives, for example, a polymeric material, to provide insulation, support, and stability.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. A device comprising:
a chip on a first substrate;
a first conductive structure formed on the chip, the conductive structure comprising a conductive pillar and a solder bump formed over the pillar, wherein the first conductive structure has an elongated cross section in a plane parallel to the first substrate;
a metal trace formed on a second substrate facing the chip;
a solder resister layer formed over the second substrate, the solder resister layer having an opening over the metal trace; and
the first conductive structure on the chip and the metal trace in the opening of the solder resister layer formed a bump-on-trace interconnect, wherein a long axis of the elongated cross section of the conductive structure is coaxial to the trace, and the trace is aligned to point to a center portion of the chip.

2. The device of claim 1, wherein the first conductive structure is located in a peripheral portion of the chip.

3. The device of claim 2, wherein the peripheral portion of the chip includes a chip corner and a chip straight edge, wherein the bump-on-trace in the chip corner is aligned along a diagonal line of the chip and the bump-on-trace along the chip straight edge is aligned perpendicular to the chip straight edge.

4. The device of claim 1, further comprising a second conductive structure having a round cross section in the plane parallel to the first substrate.

5. The device of claim 4, wherein the second conductive structure having the round cross section is located in a central portion of the chip.

6. The device of claim 1, wherein the trace has a shape selected from a group consisting of a straight line, a bent line, and a curved line.

7. The device of claim 1, wherein the trace includes a material selected from the group consisting of copper, copper/nickel alloy, copper-IT (immersion Sn), and copper-ENEPIG (electroless nickel electroless palladium immersion gold), copper-OSP (organic solderability preservatives), aluminum, aluminum, aluminum/silicon/copper alloy, titanium, titanium nitride, tungsten, polysilicon, metal silicide, copper alloy, titanium, titanium nitride, tantalum, tantalum nitride, tungsten, polysilicon, and combinations thereof.

8. A device comprising:
a chip on a first substrate, the chip having a central area, a corner area, and a peripheral edge area;
an array of first conductive structures having elongated cross sections formed in the corner area of the chip, the first conductive structures each comprising a conductive pillar and a solder bump formed over the pillar;
an array of second conductive structures having elongated cross sections formed in the peripheral edge area of the chip, the second conductive structures each comprising a conductive pillar and a solder bump formed over the pillar;
an array of metal traces on a second substrate facing the first substrate; and
the first and second conductive structures each forming a coaxial bump-on-trace interconnect with the metal traces respectively within ±30 degrees,
wherein a long axis of the elongated cross sections of the first conductive structures in the corner area of the chip points to the center area of the chip, and a long axis of the elongated cross sections of the second conductive structures in the peripheral edge area of the chip aligns perpendicular to the chip's edge.

9. The device of claim 8, further comprising an array of third conductive structures in the center area of the chip, the third conductive structures having round cross sections in the plane parallel to the first substrate.

10. The device of claim 8, wherein the first conductive structures in the corner area of the chip point to the chip center within ±15 degrees.

11. The device of claim 8, wherein the second conductive structures in the peripheral edge area of the chip align perpendicular to the chip edge within ±15 degrees.

12. The device of claim 8, wherein the arrays of the first and second conductive structures have predetermined layouts.

13. The device of claim 8, wherein the array of first conductive structures and the array of second conductive structures include sub-arrays.

14. The device of claim 13, wherein the sub-arrays have different predetermined layouts from each other.

15. The device of claim 8, wherein the traces have shapes selected from a group consisting of straight lines, bent lines, and curved lines.

16. The device of claim 8, wherein the bump-on-trace interconnect structures are staggered alternating structures.

17. A method of manufacturing a low stress chip package array, comprising:
a) providing a chip on a first substrate;
b) dividing the chip into a central area, a corner area, and a peripheral edge area;
c) generating a plurality of first conductive pillars in the corner area of the chip, the pillars having elongated cross sections in a plane parallel to the first substrate;
d) generating a plurality of second conductive pillars in the peripheral edge area of the chip, the pillars having elongated cross sections in a plane parallel to the first substrate;
e) forming a solder bump over each of the first and second conductive elongated pillars;
f) forming a plurality of trace lines on a second substrate;
g) coating a layer of solder resister over the second substrate;
h) forming a plurality of openings over the trace lines in the solder resister layer;
i) flipping the second substrate to face the first substrate; and
j) connecting the first and second conductive elongated pillars to the trace lines via the solder bumps,
wherein the long axes of the elongated cross sections of the first and second conductive pillars are coaxial with the corresponding trace lines, and
wherein the first conductive elongated pillars in the corner area of the chip align along a diagonal line of the chip and the second conductive elongated pillars in the peripheral edge area of the chip align perpendicular to the chip's edge.

18. The method of manufacturing a low stress chip package as in claim 17, wherein a substantial portion of the solder resister layer is opened in the corner area and the peripheral area of the chip.

19. The method of manufacturing a low stress chip package as in claim 17, wherein a substantial portion of the solder resister is opened in the corner area, the peripheral area, and the central area of the chip.

20. The method of manufacturing a low stress chip package as in claim 17, wherein a substantial portion of the solder resister is opened in the corner area and the peripheral area, but only portions of the solder resister is opened in the central area of the chip.
